(19) United States
(12) Patent Application Publication
(10) Pub. No.: US 2004/0014269 A1
(43) Pub. Date: Jan. 22, 2004

(54) Method of manufacturing flash memory device

(76) Inventors: Jum Soo Kim, Ichon-Shi (KR); Sung Mun Jung, Yeoju-Gun (KR); Jung Ryul Ahn, Namyangju-Shi (KR)

Correspondence Address: MORGAN LEWIS & BOCKIUS LLP, 1111 PENNSYLVANIA AVENUE NW, WASHINGTON, DC, 20004, US

(21) Appl. No.: 10/315,245

(22) Filed: Dec. 10, 2002

(30) Foreign Application Priority Data
Jul. 18, 2002 (KR) 2002-42160

(51) Int. Cl. H01L 21/8238; H01L 29/76

(52) U.S. Cl. 438/201

(57) ABSTRACT

The present invention relates to a method of manufacturing a flash memory device. The method comprises the steps of sequentially depositing a pad oxide film and a pad nitride film on a semiconductor substrate, etching the pad nitride film, the pad oxide film and the substrate using a mask for forming a device isolation film to form a trench in which the top corner of an active region has a dual profile, depositing a trench insulating film on the entire structure to bury the trench, performing a CMP process and a strip process for the trench insulating film to form the trench insulating film the top structure of which has protrusion, forming a well region through an ion implantation process, and forming a tunnel oxide film, a floating gate, a dielectric film and a control gate. Therefore, characteristics of the device can be improved by improving a phenomenon that a tunnel oxide film is made thin.

### BACKGROUND OF THE INVENTION

1. Field of the Invention

The invention relates generally to a process of forming a device isolation film in a method of manufacturing a flash memory device. More particularly, the invention relates to a method of manufacturing a flash memory device capable of preventing a phenomenon that a tunnel oxide film is made thin, by which a dual slope is formed at the top corners of a trench.

2. Description of the Prior Art

A flash memory device has a floating gate surrounded by an insulating film. In the flash memory device, a state of the cell, i.e., program and erase are determined depending on whether electrons exist in the floating film or not. This function is performed through a tunnel oxide film between the floating gate and a substrate. The operation of the flash memory device such as storing, erasing information, etc. must be performed for at least 100K cycles.

In manufacturing the flash memory device, the flash memory cells are implemented using a shallow trench isolation (STI) process as a device isolation process. The method of manufacturing flash memory device includes the steps of depositing a pad oxide film, a pad nitride film, etc. on a semiconductor substrate and then etching them to form a trench, forming an oxide film to bury the trench, and removing the pad oxide film and the pad nitride film. If this device isolation process is used, however, a moat in which an edge portion of the oxide film is concaved is generated. Further, tunnel oxide thinning in which the tunnel oxide film is made thin is generated.

FIG. 1 is a photography showing a phenomenon that the tunnel oxide film is made thin. This phenomenon do not represent a constant characteristic due to damage of an etch process for forming the trench in the flash memory device but represents an irregular characteristic.

If this phenomenon, that the tunnel oxide film is not uniformly formed but is made thin, is generated, the difference in the coupling ratio is large. Due to this, upon program and erase operations of the cell, such problems as over erase, etc. are generated, which adversely affect the device characteristic. FIG. 2 is a graph showing distribution of the cells when the flash memory device is manufactured by the device isolation process in the prior art. Further, if only the thin portions of the tunnel oxide film are used, the device may not properly operate due to lowering in the characteristic of the tunnel oxide film when the operation of the flash memory device is over 100K.

Also, as the thin portion may serves as a path of electric charge loss generating through the tunnel oxide film, there are problems that it greatly affects reliability of the device and it lowers the yield of the product. These problems are caused by over-etching generating in a subsequent cleaning process when a wall sacrificial oxidization process after a trench device isolation process is used.

### SUMMARY OF THE INVENTION

The present invention is contrived to solve the above problems and an object of the present invention is to provide a method of manufacturing a flash memory device by which a dual profile is formed at the top corners of an active region when a device isolation film is formed in a method of manufacturing the flash memory device.

In order to accomplish the above object, a method of manufacturing the flash memory device according to the present invention, is characterized in that it comprises the steps of sequentially depositing a pad oxide film and a pad nitride film on a semiconductor substrate, etching the pad nitride film, the pad oxide film and the substrate using a mask for forming a device isolation film to form a trench in which the top corner has a dual profile, depositing a trench insulating film on the entire structure to bury the trench, performing a CMP process and a strip process for the trench insulating film to form the trench insulating film the top structure of which has protrusion, forming a well region through an ion implantation process, and forming a tunnel oxide film, a floating gate, a dielectric film and a control gate.

### BRIEF DESCRIPTION OF THE DRAWINGS

The aforementioned aspects and other features of the present invention will be explained in the following description, taken in conjunction with the accompanying drawings, wherein:

FIG. 1 is a photography showing a phenomenon that a tunnel oxide film is made thin in a prior art;

FIG. 2 is a graph showing distribution of the cells when a flash memory device is manufactured by a device isolation process in a prior art;

FIG. 3A through FIG. 3G are cross sectional view of a flash memory device for explaining a method of manufacturing the flash memory device according to a preferred embodiment of the present invention;

FIG. 4 is a photography showing that the top corners of a trench have a dual profile when the flash memory device is manufactured according to the present invention;

FIG. 5 is a photography showing a profile of the final device when the flash memory device is manufactured according to the present invention;

FIG. 6 is a photography showing a detailed view of the dual profile shown in FIG. 5; and

FIG. 7 is a graph showing distribution of the cells when the flash memory device is manufactured by a device isolation process of the present invention.

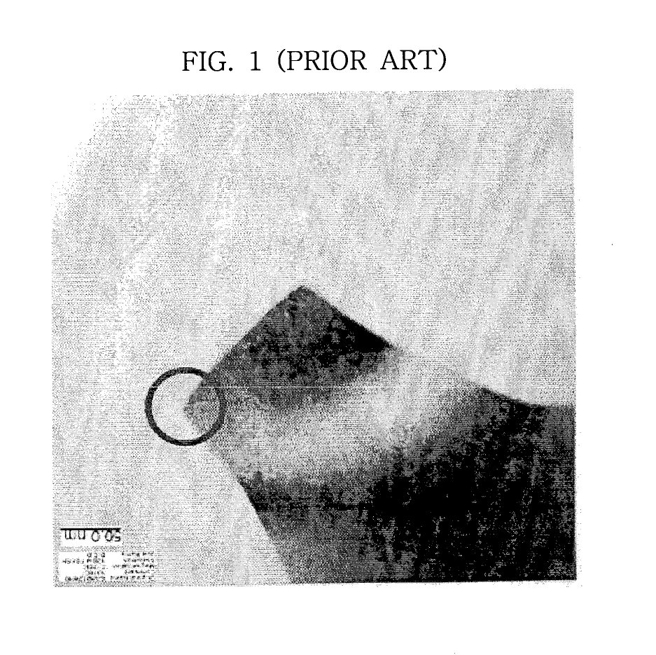

### DETAILED DESCRIPTION OF PREFERRED EMBODIMENTS

The present invention will be described in detail by way of a preferred embodiment with reference to accompanying drawings.

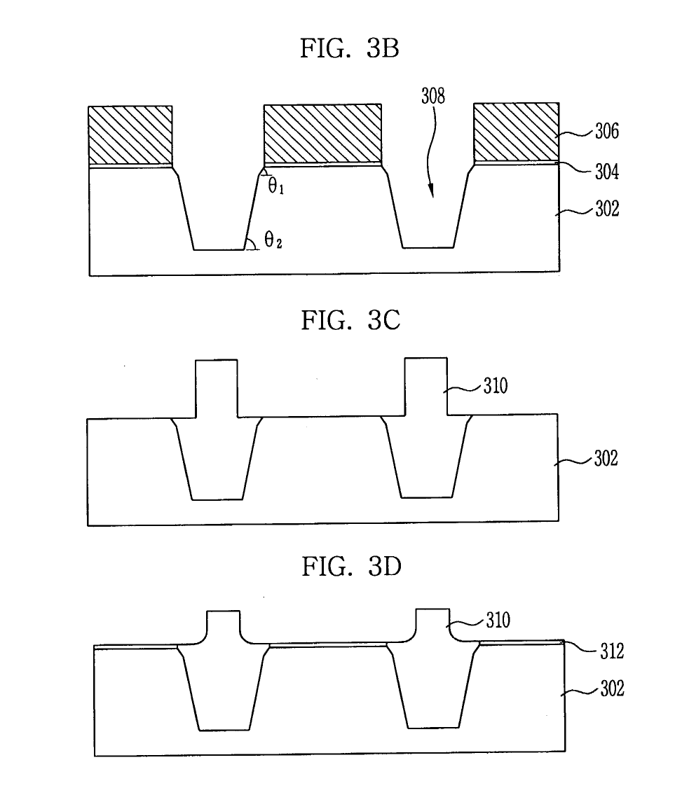

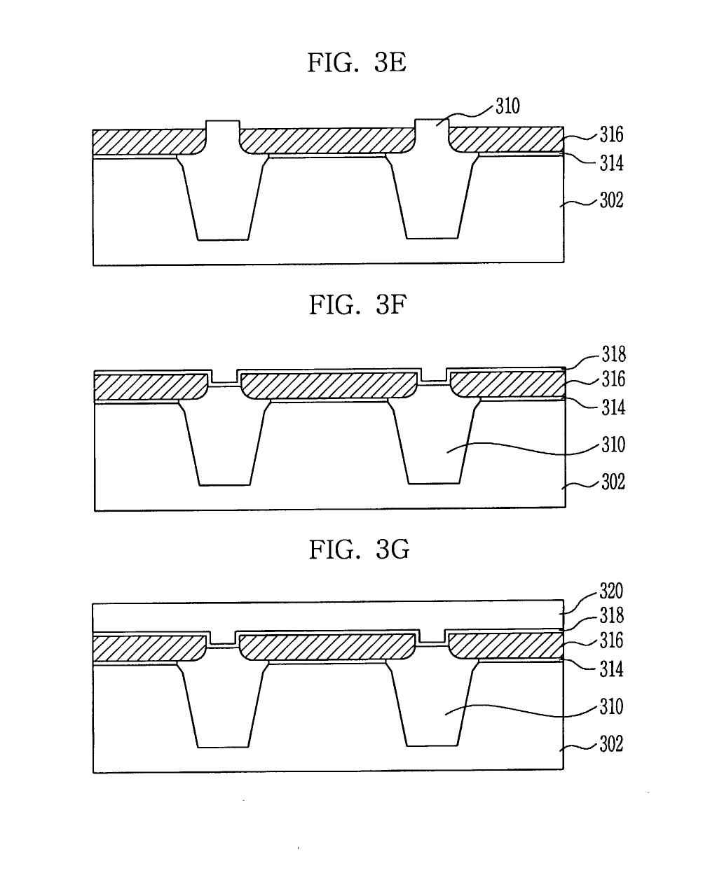

FIG. 3A through FIG. 3G are cross sectional view of a flash memory device for explaining a method of manufacturing the flash memory device according to a preferred embodiment of the present invention.

Referring now to FIG. 3A, a pad oxide film 304 is formed on a semiconductor substrate 302 in order to prohibit crystal defects on the surface of the substrate 302 or process the surface of the substrate. At this time, it is preferred that the pad oxide film 304 is formed by dry or wet oxidization method and is formed in thickness of about 70 Å through 200 Å at a temperature of 700° C. through 950° C. Next, a pad nitride film 306 is deposited on the pad oxide film 304. At this time, it is preferred that the pad nitride film 306 is formed by a LP-CVD (low pressure-chemical vapor deposition) method and is formed in thickness having the height to which a protrusion of a trench insulating film to be formed in a subsequent process can be sufficiently protruded, for example 1500 Å through 3000 Å.

After the pad nitride film 304 is formed, a trench is formed in the semiconductor substrate 302 through patterning for forming a device isolation film, thus defining a device isolation region and an active region. In other words, as shown in FIG. 3B, a photoresist pattern (not shown) defining the device isolation region is formed. Next, the pad nitride film 306, the pad oxide film 304 and the semiconductor substrate 302 are etched to form the trench 308 using the photoresist pattern as an etch mask. At this time, upon etching of the pad nitride film 306, the top corner of the trench 308 is etched to have a given slope through over-etching, thus forming a first profile. Upon etching of the semiconductor substrate, a second profile is formed. As a result, a dual profile having the two slopes is formed.

At this time, it is preferred that an angle (Θ₁) of the first profile formed through over-etching of the pad nitride film is 35° through 55° and an angle (Θ₂) of the second profile formed through etching for the semiconductor substrate 70° through 84°. Here, the pad nitride film may be etched using CF₄ gas, CHF₃ gas and Ar gas, and the semiconductor substrate may be etched using Cl₂ gas, O₂ gas and HBr gas. The pad nitride film may be etched in the pressure of about 45 mT with power of about 700W, and the semiconductor substrate may be etched in the pressure of about 35 mT with power of about 425W. The dual profile may be formed by two-step etching processes by changing an etch gas when the semiconductor substrate is etched. That is to say, the first profile is formed using CF₄ gas with power of about 400W in the pressure of about 35 mT, the second profile is formed using Cl₂ gas, O₂ gas and HBr gas with power of about 425W in the pressure of 35 mT. If the top corners of the trench 308 are formed to have the dual profile, the active region of 200 Å through 600 Å is increased by the fist slope and the depth of the first slope becomes 100 Å through 300 Å.

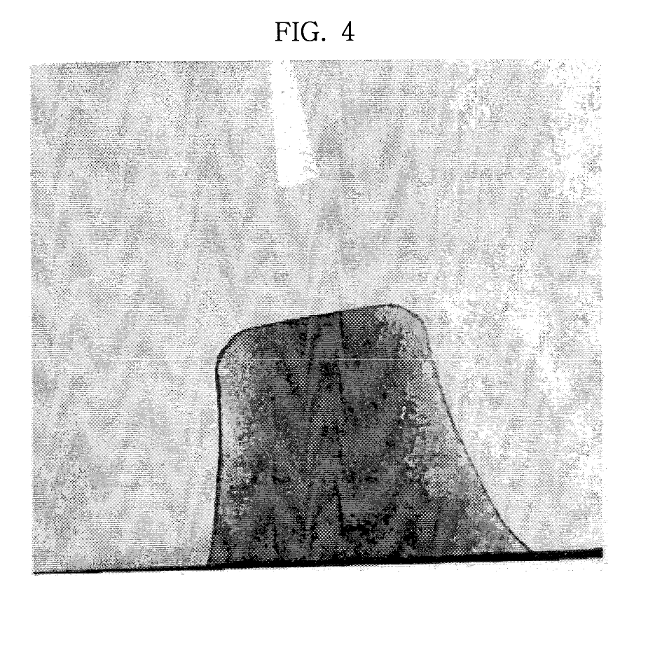

Next, in order to compensate for etch damage at the sidewall of the trench 308, a sacrificial oxide film is formed on an inner wall of the trench. At this time, it is preferred that the sacrificial oxide film (not shown) is formed by dry or wet oxidization process and is formed in thickness of about 200 Å through 400 Å at a temperature of 700° C. through 1000° C. After the sacrificial oxide film is removed by an etch solution, sidewall oxidization for removing damage due to etching of the trench is performed to form an oxide film (not shown) on the inner wall of the trench 308. At this time, the angled corner portions at the bottom and top portions of the trench are rounded by the process of the sidewall oxidation. It is preferred that the sidewall oxide film is formed in thickness of about 300 Å through 600 Å at a temperature of 800° C. through 1000° C. by means of a wet oxidization method. Also, it is preferred that an overlapped region with the field oxide film is 40% through 70%. FIG. 4 is a photography of the semiconductor device after the sacrificial oxide film and the sidewall oxide film are formed. From the drawing, it can be seen that the top corners of the trench 308 have the dual profile.

Thereafter, a liner (not shown) is formed on the entire structure. At this time, the liner serves to enhance an adhesive force with a trench insulating film to be formed in a subsequent process, prevent a moat formed by sunken hollow between the trench insulating film and the semiconductor substrate in a subsequent etch process, and prevent a leakage current. It is preferred that the liner is formed using a high-temperature oxide (HTO) film by a fineness process at a high temperature. For example, it is preferred that the liner is formed in thickness of about 50 Å through 500 Å by reaction of SiH₂CI₂ (dichlorosilane; DCS) and oxygen. At this time, another fineness process of 20 through 30 minutes at a temperature of 900° C. through 1100° C. may be added as the annealing process using N₂. Also, the liner may be formed using a nitride film instead of the oxide film.

Next, a trench insulating film (not shown) is deposited to bury the trench 308. At this time, the trench insulating film is deposited in thickness to which an upper surface of the pad nitride film 306 is sufficiently deposited while burying the trench, for example 4000 Å through 8000 Å. It is preferred that the trench insulating film is formed using a HDP (high density plasma) oxide film, so that void, etc. do not occur within the trench. However, the order of the process of forming the liner, the annealing process and the process of depositing the trench insulating film may be replaced by the order of the process of forming the liner, the process of depositing the trench insulating film and the annealing process.

After the trench is buried, a CMP (chemical mechanical polishing) process using the pad nitride film 306 as a stop barrier is performed for the entire structure to planarize the trench insulating film. A cleaning process is then performed. The cleaning process is performed in order to remove residues of the trench insulating film that may exist on the pad nitride film after the CMP process. At this time, the cleaning process is performed so that the pad nitride film is not over etched. Further, it is preferred that reduction in the height of the trench insulating film is prohibited by maximum.

Next, a strip process using H₃PO₄ (phosphoric acid) solution is performed to remove the pad nitride film, thus forming the trench insulating film 310 the top structure of which are protruded. FIG. 3C shows a cross sectional view of the flash memory device for which the above processes are all performed. From the drawing, it can be seen that the trench insulating film is formed. At this time, it is preferred that the protrusions of the trench insulating film have a thickness of 1500 Å through 2500 Å from the surface of the semiconductor 302.

A cleaning process using HF or BOE (buffer oxide etchant) is performed for the entire structure, so that the protrusions of the trench insulating film 310 are etched by a given width. At this time, the cleaning process is performed so that overlap with the field oxide film is 30% through 40% by controlling the time of the cleaning process. This free degree of the cleaning process is greatly affected by formation of the dual profile when the trench is formed. Also, the free degree is closely related to a phenomenon that the tunnel oxide film is made thin upon a subsequent process of a tunnel oxide film and affects formation of a transistor.

Referring now to FIG. 3D, a screen oxidation process is performed on the active region for the purpose of a implantation process for forming wells and implantation process for controlling threshold voltage, thus forming a screen oxide film 312 of 30 Å through 100 Å in thickness. Next, the implantation process is performed to form a well region (not shown) in the active region of the semiconductor substrate 302 and the implantation process is then performed to control threshold voltage.

By reference to FIG. 3e, after the screen oxide film 312 is removed by a cleaning process, a tunnel oxide film 314 is formed at the portion from which the screen oxide film 312 is removed. At this time, the tunnel oxide film 314 is formed by performing a wet oxidization method at a temperature of 750 through 800° C. and then performing an annealing process using N₂ at a temperature of 900 through 910° C. for 20 through 30 minutes, in order to minimize an interfacial defect density with the semiconductor substrate 302. The thickness at the corner portions of the tunnel oxide film may be thicker by 1.05 through 1.4 times than the central portion of the tunnel oxide film. A cleaning process may be formed in order to adjust the thickness.

After the tunnel oxide film is deposited, a first polysilicon film 316 is deposited on the entire structure and a planarization process is then performed. At this time, it is preferred that the thickness of the first polysilicon film is thicker about 200 Å through 1000 Å than the top surface of the protrusion of the trench insulating film. It is also preferred that the CMP process is performed so that the first polysilicon film uniformly remains in thickness 700 Å through 1200 Å while the floating gates can be completely separated by the trench insulating film.

Referring now to FIG. 3f, the trench insulating film 310 protruded between the first polysilicon films 316 is removed by a cleaning process using HF or BOE. A dielectric film 318 is formed on the first polysilicon film and the trench insulating film. At this time, it is preferred that the dielectric film has a structure of an oxide film/a nitride film/an oxide film/a nitride film, i.e., the structure of the ONON (SiO₂/Si₃N₄/SiO₂/Si₃N₄), or a structure of an oxide film/a nitride film/an oxide film, i.e., the structure of the ONO (SiO₂/Si₃N₄/SiO₂), and is formed in thickness of 35 Å through 80 Å.

By reference to FIG. 3G, a second polysilicon film 320 for forming a control gate and a silicide film are formed and a gate patterning process is then performed.

Subsequent processes are common processes of the flash memory device. Thus, a detailed description of them will be omitted.

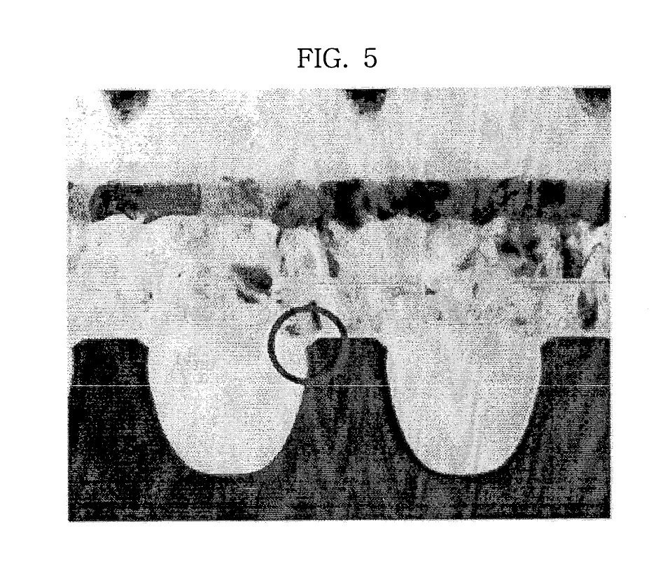

An explanation will be now made by reference to FIG. 5 through FIG. 7.

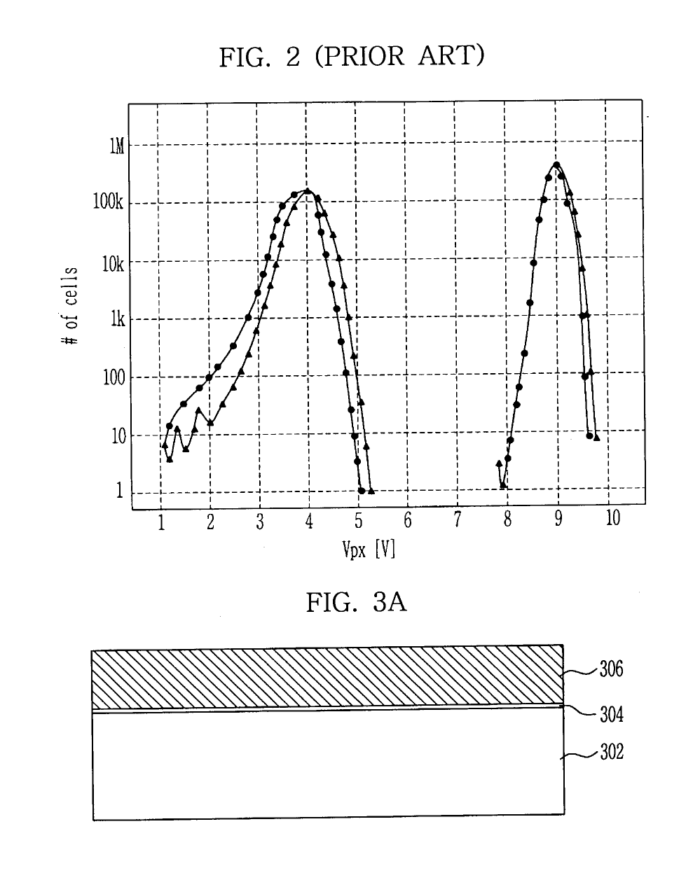

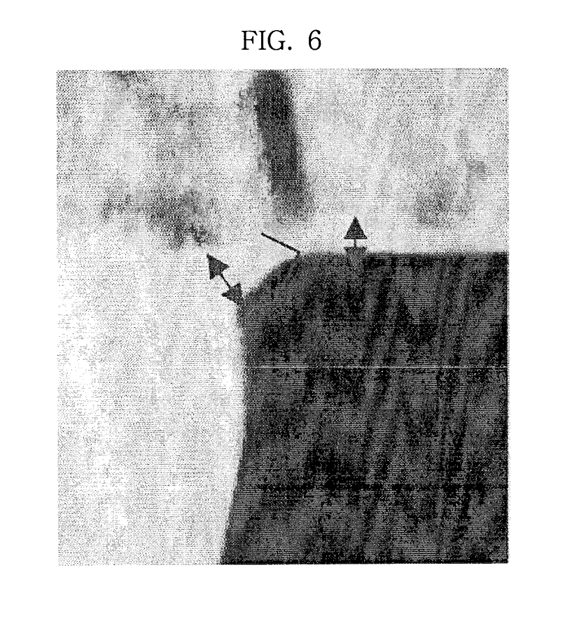

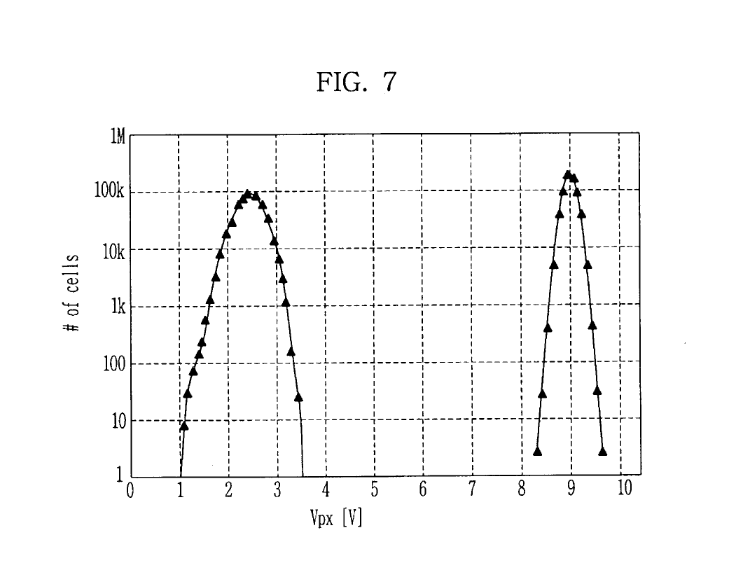

FIG. 5 is a photography showing a profile of the final device when the flash memory device is manufactured according to the present invention. If this dual profile is used, generation of a moat due to over wet etch used upon a process of forming a self-aligned floating gate and a phenomenon that the tunnel oxide film is made thin can be mitigated. Also, FIG. 6 is a photography showing the detailed view of the dual profile shown in FIG. 5. From the drawing, it can be seen that the oxide film at the edge of the active region is larger than the oxide film at the center of the active region. FIG. 7 is a graph showing distribution of the cells when the flash memory device is manufactured by a device isolation process of the present invention. From the drawing, it can be seen that FIG. 7 shows improved distribution of the cells compared to that in FIG. 2.

As mentioned above, according to the present invention, when a device isolation film is formed in the method of manufacturing a flash memory device, a dual profile is formed at the top corners of a trench. Therefore, the present invention has an advantageous effect that it can improve characteristics of the device by prohibiting a phenomenon that a tunnel oxide film is made thin. Further, a thick tunnel oxide film is formed at the edge of the active region. Therefore, the present invention has outstanding advantages that it can improve characteristics of the cell, improve the coupling ratio and easily implement a high-integrated flash memory device, since a margin upon a wet etching process is secured.

The present invention has been described with reference to a particular embodiment in connection with a particular application. Those having ordinary skill in the art and access to the teachings of the present invention will recognize additional modifications and applications within the scope thereof.

It is therefore intended by the appended claims to cover any and all such applications, modifications, and embodiments within the scope of the present invention.

What is claimed is:

1. A method of manufacturing a flash memory device, comprising the steps of:
(a) sequentially depositing a pad oxide film and a pad nitride film on a semiconductor substrate;
(b) etching the pad nitride film, the pad oxide film and the substrate using a mask for forming a device isolation film to form a trench in which the top corners have a dual profile;
(c) depositing a trench insulating film on the entire structure to bury the trench;
(d) performing a CMP process and a strip process for the trench insulating film to form the trench insulating film the top structure of which have protrusions;
(e) forming a well region through an ion implantation process; and
(f) forming a tunnel oxide film, a floating gate, a dielectric film and a control gate.

2. The method as claimed in claim 1, wherein formation of the dual profile includes forming a first profile upon over-etching of the pad nitride film and a second profile upon etching of the substrate.

3. The method as claimed in claim 2, wherein an angle of the first profile is 35° through 55° centering on the plan of the substrate, and an angle of the second profile is 70° through 84° centering on the plan of the substrate.

4. The method as claimed in claim 2, wherein the length of the active region is increased toward the trench by 200 Å through 600 Å by forming the first profile, and the depth of the first profile is 100 Å through 300 Å.

5. The method as claimed in claim 1, wherein the dual profile is formed by two-step etching processes by changing an etch gas when the semiconductor substrate is etched.

6. The method as claimed in claim 1, wherein the pad oxide film is formed by dry or wet oxidization method and is formed in thickness of 70 Å through 200 Å at a temperature of 700° C. through 950° C.

7. The method as claimed in claim 1, wherein the pad nitride film is formed by a LP-CVD method and is formed in thickness of 1500 Å through 3000 Å.

8. The method as claimed in claim 1, further comprising the steps of after the step (b),
forming a sacrificial oxide film on an inner wall of the trench;
removing the sacrificial oxide film using an etch solution and then forming a sidewall oxide film on the inner wall of the trench; and
forming a liner on the entire structure.

9. The method as claimed in claim 8, wherein the sacrificial oxide film is formed by dry or wet oxidization method and is formed in thickness of 200 Å through 400 Å at a temperature of 700° C. through 1000° C.

10. The method as claimed in claim 8, wherein the sidewall oxide film is formed to make rounded the angled corner portions at the top and bottom of the trench and is formed in thickness of 300 Å through 600 Å at a temperature of 800° C. through 1000° C. by means of a wet oxidization process.

11. The method as claimed in claim 8, wherein the liner is formed using a high temperature oxide (HTO) film and is formed in thickness of 50 Å through 500 Å using reaction of DCS and oxygen.
